(19) United States
(12) Patent Application Publication
(10) Pub. No.: US 2026/0282800 A1
(43) Pub. Date: Sep. 17, 2026

(54) Semiconductor Device and Method of Making Using Microwave Based Debonding

(71) Applicant: JCET STATS ChipPAC Korea Limited, Incheon (KR)

(72) Inventors: Yeojun Yun, Incheon (KR); Minsung Lee, Incheon (KR); HeeSoo Lee, Incheon (KR)

(73) Assignee: JCET STATS ChipPAC Korea Limited, Incheon (KR)

(21) Appl. No.: 19/079,649

(22) Filed: Mar. 14, 2025

(51) Int. Cl. H01L 21/67; C09J 5/00; H01L 21/304; H01L 21/683; H01L 21/78; H01L 23/31

(52) U.S. Cl. CPC H10P 72/0428; C09J 5/00; H10P 52/00; H10P 54/00; H10P 72/74; H10W 74/117; C09J 2301/502; H10P 72/7416

(57) ABSTRACT

A semiconductor device manufacturing process is performed by providing a carrier and disposing an adhesive coating over the carrier. The adhesive coating includes polypropylene carbonate, graphite powder, and a photo acid generator or thermal acid generator. A semiconductor wafer is attached to the carrier using the adhesive coating. Backside processing is performed on the semiconductor wafer while the semiconductor wafer is attached to the carrier. The semiconductor wafer is debonded from the carrier by applying microwave energy to the adhesive coating.

### FIELD OF THE INVENTION

The present invention relates in general to semiconductor devices and, more particularly, to a semiconductor device and methods of making using microwave based debonding.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. Smaller and thinner semiconductor devices are typically supported by a temporary carrier during processing. Semiconductor devices being processed during manufacturing are attached to a temporary carrier using a temporary bonding/debonding (TBDB) technology. TBDB technology greatly contributes to reliable fabrication.

The rapid development of large-scale, high precision, and ultra-thin devices in the semiconductor field has required the development of more stringent requirements for TBDB technologies. TBDB technology is required because there is a possibility of damage in handling the thin wafers or embedded die. However, existing debonding methods can induce signal and performance degradation in some devices. To overcome these technical limitations in the prior art, a need exists for an improved debonding method.

### BRIEF DESCRIPTION OF THE DRAWINGS

FIGS. 1a and 1b illustrate a semiconductor wafer with a plurality of semiconductor die separated by a saw street;

FIGS. 2a-2m illustrate backside processing on a thinned semiconductor wafer;

FIGS. 3a-3i illustrate backside processing on a thinned reconstituted wafer;

FIGS. 4a-4c illustrate forming a semiconductor package with the semiconductor die; and

FIGS. 5a and 5b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

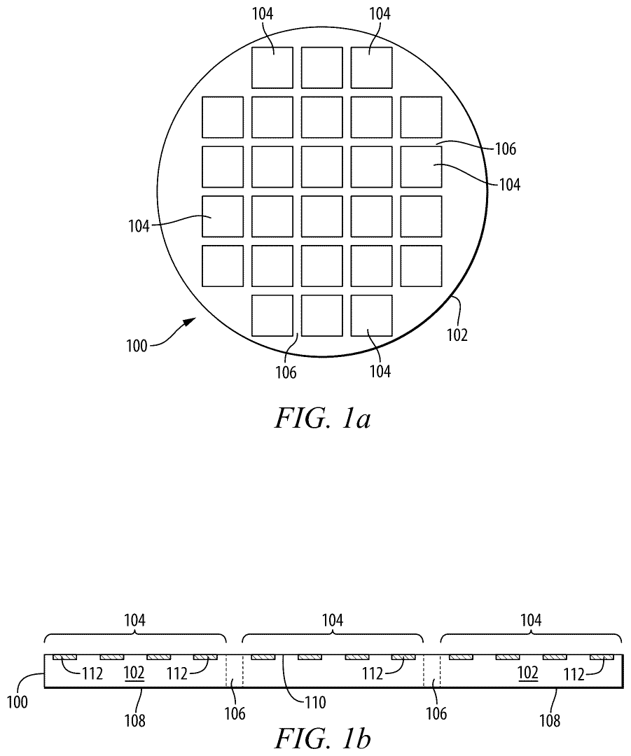

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

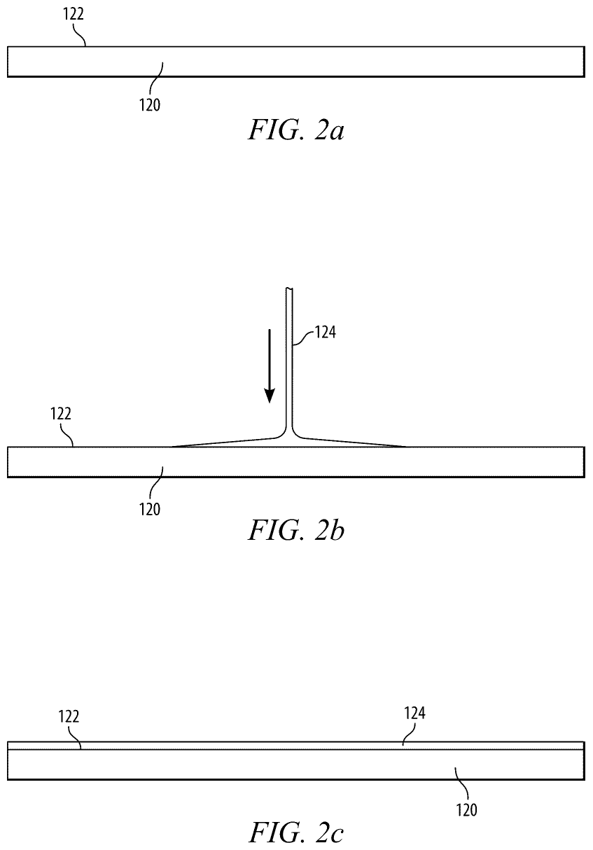

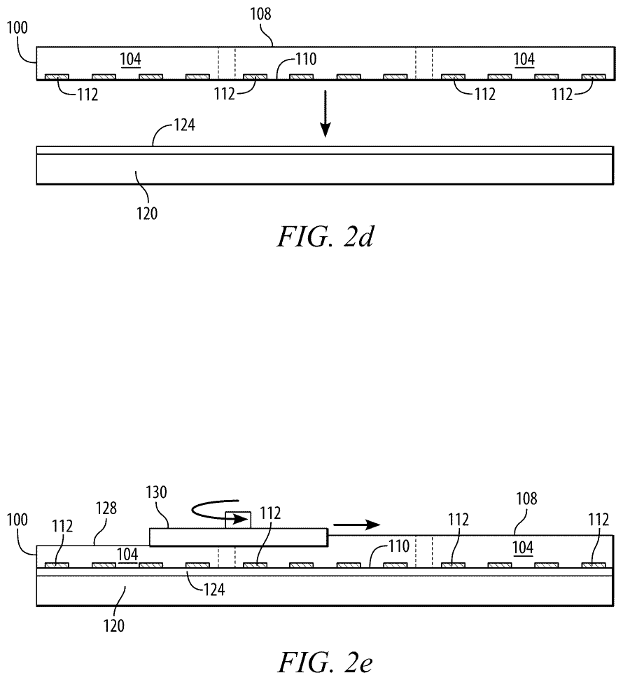

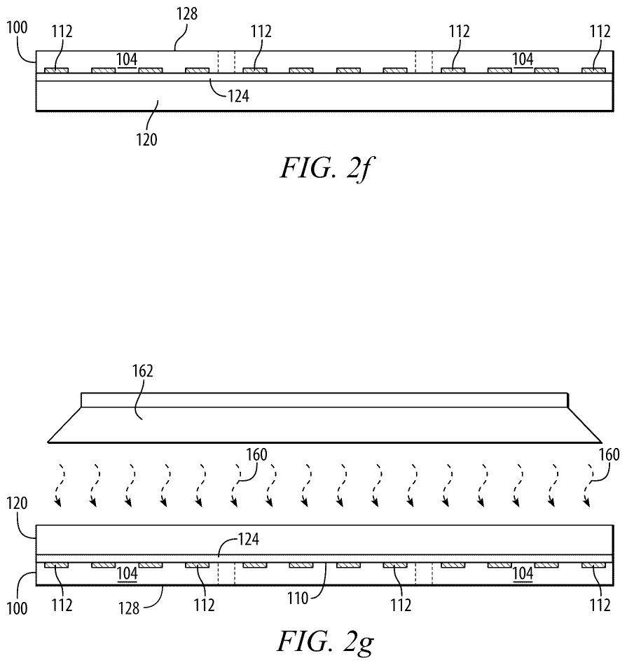

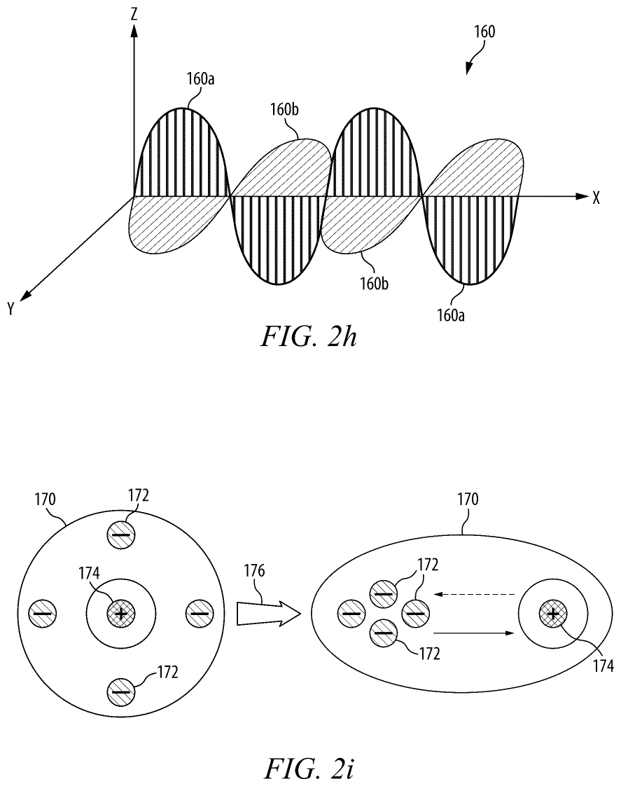

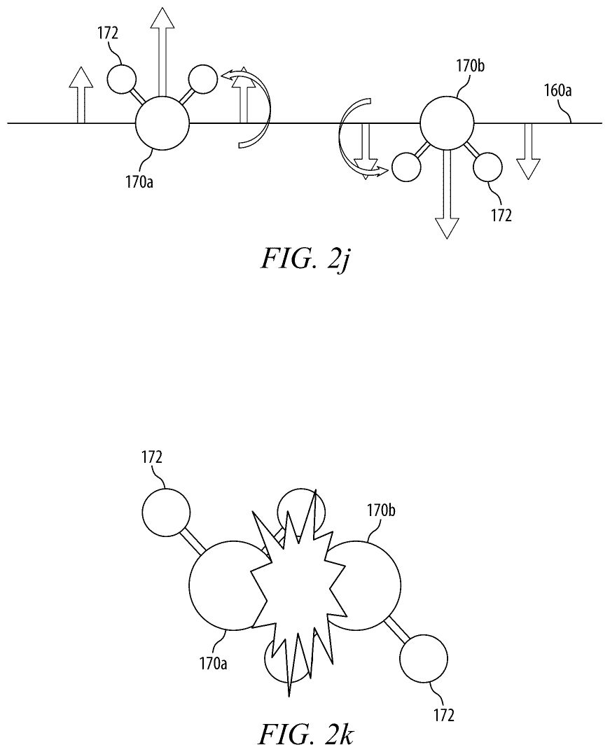

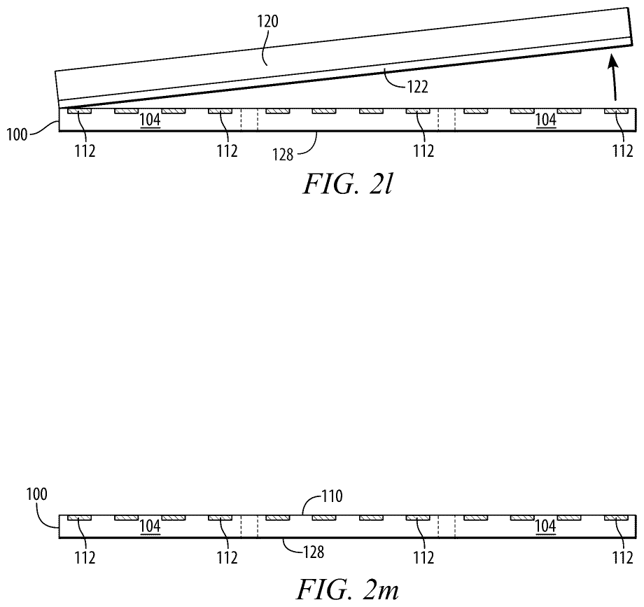

FIGS. 2a-2m illustrate temporary bonding and debonding of semiconductor wafer 100 onto a carrier 120. FIG. 2a shows a cross-section of carrier 120. Carrier 120 can be formed of any suitable material that microwaves can penetrate without significant energy loss, e.g., glass or ceramic. Carrier 120 can be formed from any suitable rigid material in other embodiments. Carrier 120 includes a width, diameter, or footprint that is equal to or larger than semiconductor wafer 100. Carrier 120 includes a top surface 122 that will be used to support wafer 100 for backside processing.

In FIG. 2b, an adhesive layer or coating 124 is applied to surface 122 of carrier 120 by spin coating. Coating 124 is dropped at the center of carrier 120 as a thin stream or flow as shown, or a series of discrete drops of the coating material. Carrier 120 rotates to use centrifugal force to evenly spread adhesive coating 124 across surface 122 as shown in FIG. 2c. In other embodiments, adhesive coating 124 is applied to carrier 120 by PVD, CVD, lamination, spray coating, sintering, thermal oxidation, paste printing, compression molding, transfer molding, liquid encapsulant molding, vacuum lamination, or another suitable application process.

Adhesive coating 124 comprises polar atoms or molecules that absorb microwave energy and convert the microwave energy to thermal energy or heat, as well as an additive that reduces the adhesive characteristic of the coating in response to the generated thermal energy. For the polar material, adhesive coating 124 contains polypropylene carbonate (PPC). The carbonate linkages (—O—CO—O—) in PPC are polar due to the electronegativity difference between oxygen and carbon. In other embodiments, adhesive coating 124 includes any polar material suitable to convert microwave energy to thermal energy.

For the detach additive, adhesive coating 124 includes a photo acid generator (PAG) and graphite powder. In some embodiments, the PAG is 4-isopropyl-4′-methyl-diphenyliodonium tetra(pentafluorophenyl)borate. Other suitable photo acid generators or thermal acid generators (TAG) are used in other embodiments. A combination of PPC, PAG or TAG, and graphite or another carbon is effective for microwave-based bonding and de-bonding. PPC converts microwave energy to thermal energy. Graphite helps distribute the thermal energy uniformly throughout adhesive coating 124. The PAG or TAG releases acid in response to the thermal energy, which reduces the adhesive effect of adhesive coating 124. Some embodiments can leave out the graphite powder if microwave energy can be sufficiently uniformly applied to adhesive coating 124 without graphite.

In FIG. 2d, semiconductor wafer 100 is disposed over and then mounted onto carrier 120 using adhesive coating 124 as an adhesive for attachment. Wafer 100 is mounted or attached to carrier 120 with active surface 110 oriented toward the carrier so that back surface 108 remains exposed for processing.

Backside processing typically includes a thinning process as shown in FIG. 2e with grinder 130. Grinder 130 spins against back surface 108 and has an abrasive surface configured to remove a portion of wafer 100 to reduce a thickness of the wafer. Back surface 108 is removed and a new back surface 128 is exposed. FIG. 2f shows wafer 100 after thinning, with back surface 128 being closer to active surface 110 than back surface 108 was before thinning. Any desired additional backside processing can occur at this stage, e.g., metallization, passivation, via formation, laser marking, or cleaning. Wafer 100 is protected or supported during backside processing by being attached to carrier 120.

After all desired backside processing is completed, wafer 100 is removed from carrier 120 by applying microwave energy 160 to the carrier in FIG. 2g. Microwave energy 160 is generated by a microwave emitter 162 disposed over carrier 120 opposite semiconductor wafer 100, and travels toward carrier 120. Carrier 120 is formed of a material that allows microwave energy 160 to pass through without significant absorption or energy loss. The PPC in adhesive coating 124 generates thermal energy in response to the microwave energy.

FIG. 2h illustrates a schematic view of a single photon of microwave energy 160 travelling along the X axis from left-to-right. Microwave energy 160, being a form of electromagnetic radiation, includes an electrical component 160a and a magnetic component 160b. Electrical component 160a oscillates in the X-Z plane and magnetic component 160b oscillates in the X-Y plane. Microwave energy 160 can be applied at a frequency in the range from 1 GHz to 10 GHz. The frequency of microwave energy 160 can be changed during irradiation for reflow, e.g., using a variable-frequency microwave (VFM) system. In one embodiment, microwave energy 160 is changed from 5.65 GHz to 6.6GHz over the course of one minute.

As microwave energy 160 passes through matter, e.g., adhesive coating 124, the electrical component 160a oscillating distorts the cloud of negatively charged electrons around positive atomic nuclei. FIG. 2i illustrates the distortion effect. On the left side of FIG. 2i is an atom 170 without microwave energy 160 applied. Electrons 172 are evenly distributed around each side of nucleus 174. On the right side of FIG. 2i, with microwave energy 160 applied as indicated by arrow 176, electrons 172 are all pushed to one side of nucleus 174 by the electrical field of electrical component 160a.

As electrical component 160a passes by and through atoms and molecules, the molecules are polarized in an oscillating fashion due to the electrical field oscillating as shown in FIG. 2h. FIG. 2j shows that atom 170 is polarized in two opposing directions depending on which part of electrical component 160a is disposed at or adjacent to that specific atom. Atom 170a has electrons 172 oriented upward in FIG. 2j because electrical component 160a has its electrical field polarized in that direction next to atom 170a. Atom 170b has electrons 172 oriented downward in FIG. 2j because electrical component 160a has its electrical field polarized in that direction next to atom 170b. Polarized molecules can be similarly rotated by microwave energy 160. Microwaves induce molecular rotation without destroying molecular bonds due to having a low energy per photon.

As nearby atoms or molecules continually oscillate in response to microwave energy 160, the atoms or molecules will periodically collide with each other as shown in FIG. 2k. Friction energy of colliding atoms or molecules converts to thermal energy. In the case of adhesive coating 124, the PPC molecules oscillate due to the application of microwave energy 160, generating thermal energy in the adhesive coating. In one embodiment, microwave energy 160 is controlled to maintain a temperature of wafer 100 in the range of 100-180° C. The carbon in adhesive coating 124 helps to evenly dissipate the thermal energy throughout the adhesive coating. The PAG releases an acid in response to the thermal energy, which reduces the adhesive properties of adhesive coating 124.

The acid released by the PAG in adhesive coating 124 degrades the adhesive properties of the adhesive coating to release wafer 100 from carrier 120 in FIG. 2l. FIG. 2m shows wafer 100 after thinning and after carrier 120 is removed. Semiconductor wafer 100 with thinned semiconductor die 104 is ready to be singulated, packaged, and inserted into a larger electrical system. Debonding with microwave energy provides a uniform application of thermal energy to adhesive layer 124, thus reducing warpage. Microwave-based debonding also reduces unintended signal and performance degradation issues that can arise in semiconductor die 104 using prior art debonding techniques.

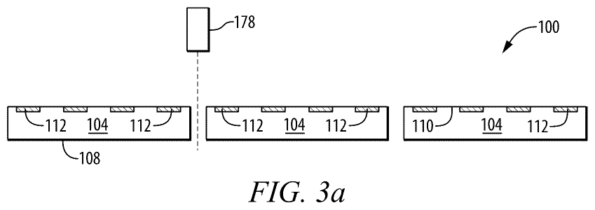

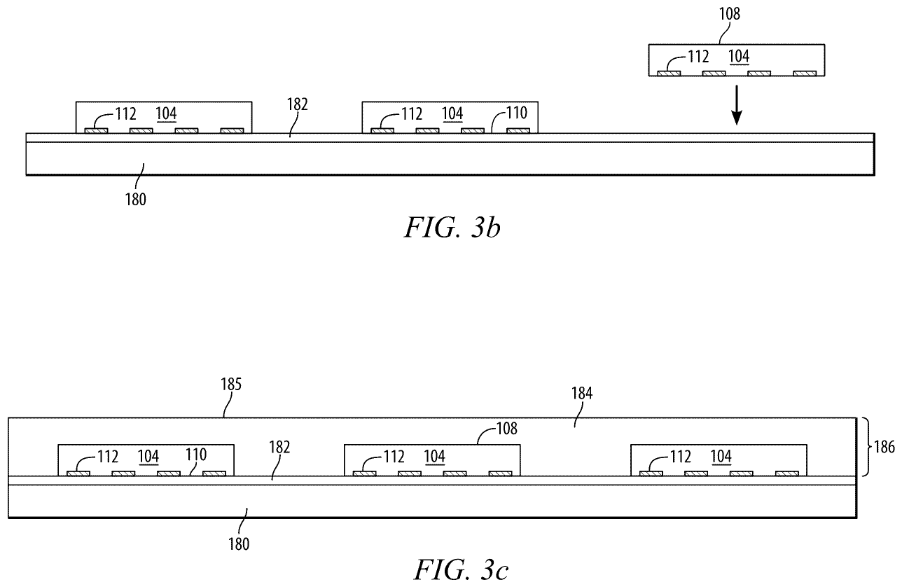

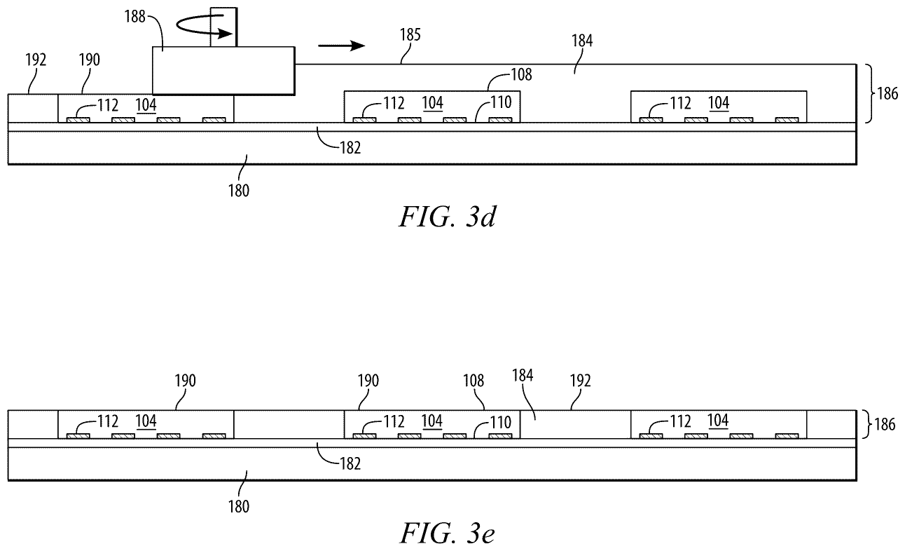

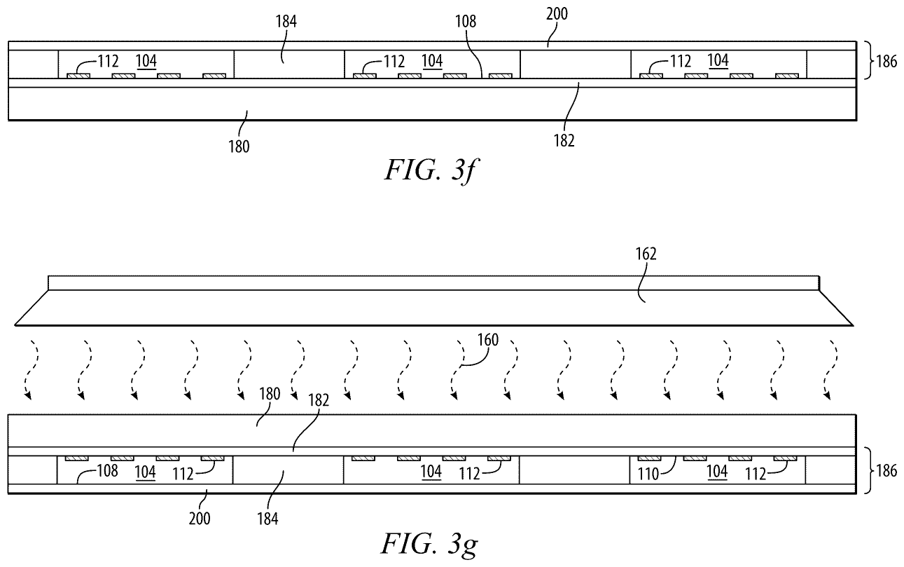

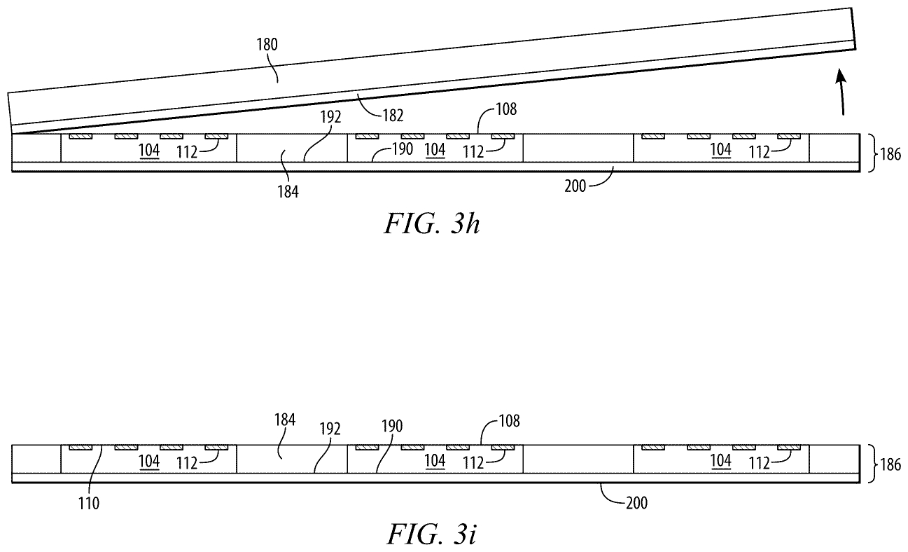

FIGS. 3a-3i illustrate temporary bonding of individual semiconductor die to form a reconstituted wafer and debonding of the reconstituted wafer as an alternative to the flow shown in FIGS. 2a-2m. In FIG. 3a, semiconductor wafer 100 is singulated through saw street 106 using a saw blade or laser cutting tool 178 into individual semiconductor die 104. The individual semiconductor die 104 can be inspected and electrically tested for identification of known good die or unit after singulation. Semiconductor wafer 100, and therefore the singulated semiconductor die 104, remains at full thickness from FIG. 1b, rather than being thinned prior to singulation as shown in FIGS. 2a-2m.

In FIG. 3b, semiconductor die 104 are picked and placed onto a carrier 180 with adhesive coating 182. Carrier 180 is substantially the same as or similar to carrier 120 above. Adhesive coating 182 is substantially the same as or similar to adhesive coating 124 above, including a combination of PPC, PAG, and graphite in one embodiment. Semiconductor die 104 are disposed with active surface 110 on adhesive coating 182.

An encapsulant 184 is deposited to cover semiconductor die 104 and carrier 120 in FIG. 3c. Encapsulant 184 is deposited using a paste printing, compressive molding, transfer molding, liquid encapsulant molding, vacuum lamination, spin coating, or another suitable applicator. Encapsulant 184 can be liquid or granular polymer composite material, such as epoxy resin, epoxy acrylate, or polymer, with or without an added filler. Encapsulant 184 completely covers semiconductor die 104 such that a back surface 185 of the encapsulant extends above each of the semiconductor die. In other embodiments, encapsulant 184 is deposited coplanar to back surfaces 108 of semiconductor die 104 using, e.g., film-assisted molding. The combination of semiconductor die 104 embedded in encapsulant 184 forms a reconstituted wafer 186.

In FIG. 3d, reconstituted wafer 186 is backgrinded with grinder 188 to remove encapsulant 184 over semiconductor die 104. Grinder 188 works similarly to grinder 130 above, but may have a different configuration, e.g., a different grit suitable to grind both encapsulant 184 and semiconductor die 104. Grinder 188 thins down encapsulant 184 starting with top surface 185 until semiconductor die 104 are reached and exposed, then continues grinding until the semiconductor die are thinned to their desired final thickness. Backgrinding creates a new back surface 190 of semiconductor die 104 and new back surface 192 of encapsulant 184. Back surfaces 190 and 192 are coplanar.

FIG. 3e shows reconstituted wafer 186 after backgrinding, ready for backside processing. Any desired backside processing can occur at this stage, e.g., metallization, passivation, via formation, laser marking, or cleaning. Semiconductor die 104 are protected during backside processing by being attached to carrier 120 and embedded in encapsulant 184.

FIG. 3f shows an insulating layer 200 formed over back surfaces 190 and 192 as part of backside processing. Insulating layer 200 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI), benzocyclobutene (BCB), polybenzoxazoles (PBO), and other material having similar insulating and structural properties. Insulating layer 200 can be formed using PVD, CVD, printing, lamination, spin coating, spray coating, sintering, or thermal oxidation. Any insulating, passivation, or dielectric layer mentioned above or below can be formed using any of the materials or methods described for insulating layer 200.

After all desired backside processing is completed, carrier 180 is removed by debonding adhesive coating 182 as described above for carrier 120 and adhesive coating 124. Microwaves 160 are applied to adhesive coating 182 through carrier 180 in FIG. 3g. The microwaves oscillate polar molecules or atoms in adhesive coating 182, generating thermal energy. The thermal energy causes the PAG or TAG in adhesive coating 182 to release acid to reduce the adhesive properties of the adhesive coating, thereby allowing carrier 180 to be removed in FIG. 3h.

FIG. 3i shows reconstituted wafer 186 after backside processing and removal of carrier 180. Reconstituted wafer 186, with embedded semiconductor die 104, can proceed to the packaging process. Temporary bonding and debonding with microwave energy has the same benefits for reconstituted wafer 186 as with semiconductor wafer 100 above. While FIGS. 3a-3i show thinning semiconductor die 104 as part of reconstituted wafer 186, other embodiments first thin semiconductor die 104 as shown in FIGS. 2a-2m and then form a reconstituted wafer, as shown in FIGS. 3a-3i but starting with the thinned die. The pre-thinned semiconductor die can be further thinned as part of a reconstituted wafer, the backgrinding step can be skipped altogether, or the backgrinding step of FIG. 3d can remove only encapsulant without significantly further thinning semiconductor die 104. In other embodiments, backside processing can be performed using the process shown in FIGS. 2a-2m for a semiconductor wafer 100, or the process shown in FIGS. 3a-3i for reconstituted wafer 186, without performing the backgrinding or thinning step. Temporary bonding and debonding with microwave detach as taught can provide the same benefits with wafer or die that have already been thinned, or simply do not need to be thinned, but do need to be backside processed.

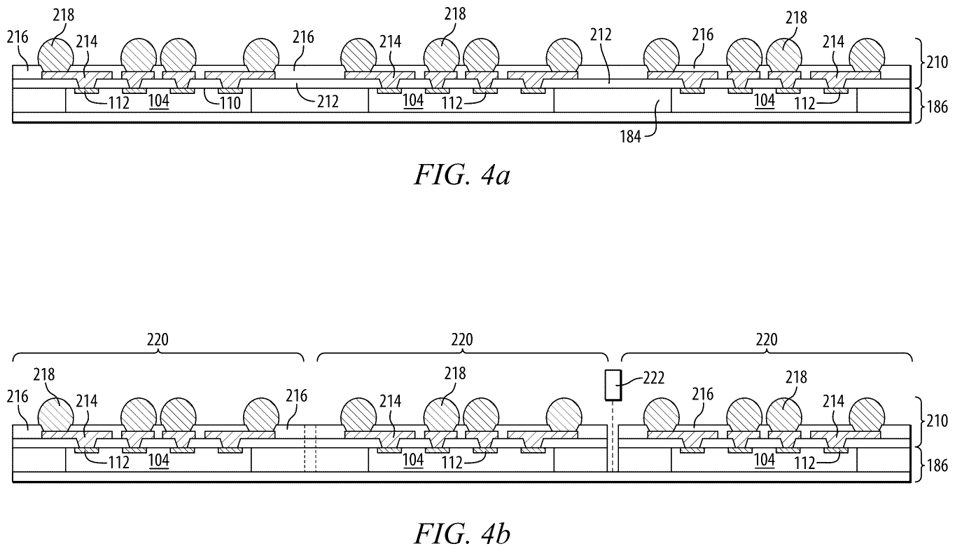

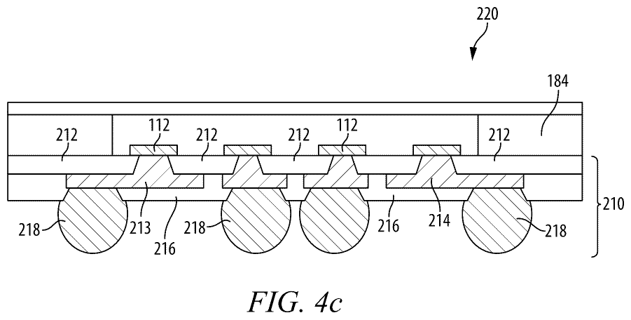

FIGS. 4a-4c illustrate one embodiment of forming a semiconductor package based on reconstituted wafer 186. In FIG. 4a, a build-up interconnect structure 210 is formed over reconstituted wafer 186. Build-up interconnect structure 210 is so-called because the interconnect structure is formed by building up conductive and insulating layers on top of a substrate, e.g., reconstituted wafer 186. Insulating layer 212 is formed on reconstituted wafer 186 using the methods and materials described above for insulating layer 200. Openings are formed through insulating layer 212 to expose contact pads 112 of semiconductor die 104.

A conductive layer 214 is formed over insulating layer 212 and into the openings through insulating layer 212 to physically contact and electrically connect to contact pads 112. Conductive layer 214 is patterned using a mask, photolithography, chemical etching, laser ablation, jet printing, or another suitable method to form a redistribution layer (RDL) fanning out from contact pads 112. In other embodiments, conductive layer 214 forms a fan-in interconnect structure. The individual conductive traces of conductive layer 214 have one end at a contact pad 112 and have contact pads or capture pads formed at their opposite ends.

Another insulating layer 216 is formed over conductive layer 214 as described for insulating layer 212. Openings are formed through insulating layer 216 to expose contact pads of conductive layer 214. Any number of additional insulating and conductive layers can be interleaved over conductive layer 214 and insulating layer 216 to add RDL layers and allow more complex signal routing.

An electrically conductive bump material is deposited over conductive layer 214 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 214 using a suitable attachment or bonding process. In one embodiment, the bump material is reflowed by heating the material above its melting point to form bumps 218. In one embodiment, bump 218 is formed over an under-bump metallization (UBM) having a wetting layer, barrier layer, and adhesion layer. Bump 218 can also be compression bonded or thermocompression bonded to conductive layer 214.

In FIG. 4b, encapsulant 184 and build-up interconnect structure 210 are singulated into individual semiconductor packages 220 using a saw blade or laser cutting tool 222. FIG. 4c shows a completed semiconductor package 220. Contact pads 112 are electrically connected to solder bumps 218 by conductive layer 214 and any additional RDL layers that are optionally formed. Semiconductor die 104 can be packaged using any suitable packaging methods, with or without being a part of reconstituted wafer 186. Being supported by a carrier during backside processing protects semiconductor die 104 from damage. Being attached to the carrier with an adhesive that can be microwave debonded reduces warpage and other damage during the debonding process.

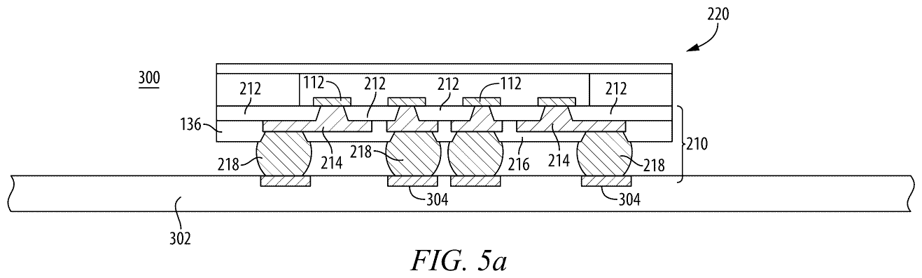

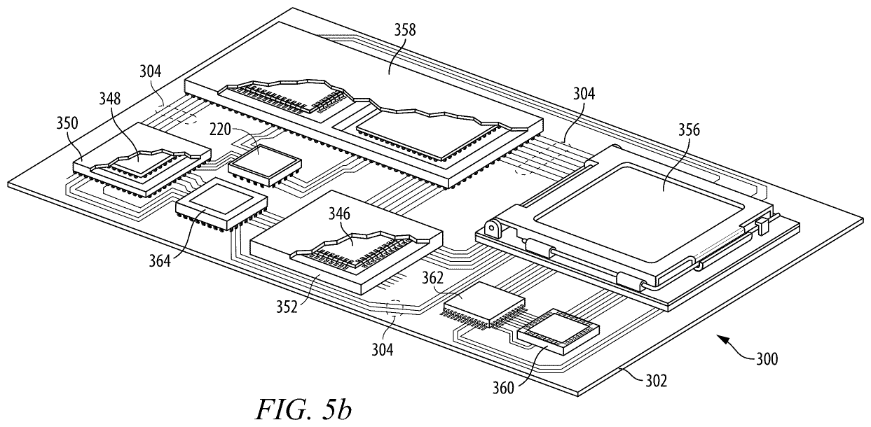

FIGS. 5a and 5b illustrate integrating the above-described semiconductor packages, e.g., semiconductor package 220, into a larger electronic device 300. FIG. 5a illustrates a partial cross-section of semiconductor package 220 mounted onto a printed circuit board (PCB) or other substrate 302 as part of electronic device 300. Solder bumps 218 are reflowed onto conductive layer 304 of PCB 302 to physically attach and electrically connect the semiconductor package to the PCB. In other embodiments, thermocompression or another suitable attachment and connection methods are used. In some embodiments, an adhesive or underfill layer is used between semiconductor package 220 and PCB 302. Semiconductor die 104 is electrically coupled to conductive layer 304 through build-up interconnect structure 210.

FIG. 5b illustrates electronic device 300 having a chip carrier substrate or PCB 302 with a plurality of semiconductor packages disposed on a surface of PCB 302, including semiconductor package 220. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a carrier;
disposing an adhesive coating over the carrier, wherein the adhesive coating includes polypropylene carbonate, graphite powder, and a photo acid generator or thermal acid generator;
attaching a semiconductor wafer to the carrier using the adhesive coating;
performing backside processing on the semiconductor wafer while the semiconductor wafer is attached to the carrier; and
debonding the semiconductor wafer from the carrier by applying a microwave energy to the adhesive coating.

2. The method of claim 1, further including providing the carrier to include ceramic or glass, wherein the microwave energy is transmitted through the carrier to the adhesive coating.

3. The method of claim 1, further including:
disposing a microwave emitter over the carrier opposite the semiconductor wafer; and
generating the microwave energy using the microwave emitter.

4. The method of claim 1, wherein performing backside processing includes backgrinding to reduce a thickness of the semiconductor wafer.

5. The method of claim 1, further including:
singulating the semiconductor wafer to separate a plurality of semiconductor die from each other;
depositing an encapsulant over the semiconductor die to form a reconstituted wafer; and
forming a build-up interconnect structure over the reconstituted wafer.

6. The method of claim 1, further including applying the microwave energy at a frequency of between 1 and 10 GHz.

7. A method of making a semiconductor device, comprising:
providing a carrier;
disposing an adhesive coating over the carrier, wherein the adhesive coating includes polypropylene carbonate and either a photo acid generator or thermal acid generator;
attaching a semiconductor wafer to the carrier using the adhesive coating; and
debonding the semiconductor wafer from the carrier by applying microwave energy to the adhesive coating.

8. The method of claim 7, further including providing the carrier to include ceramic or glass, wherein the microwave energy is transmitted through the carrier to the adhesive coating.

9. The method of claim 7, further including:
disposing a microwave emitter over the carrier opposite the semiconductor wafer; and
generating the microwave energy using the microwave emitter.

10. The method of claim 7, further including:
singulating the semiconductor wafer to separate a plurality of semiconductor die from each other;
depositing an encapsulant over the semiconductor die to form a reconstituted wafer; and
forming a build-up interconnect structure over the reconstituted wafer.

11. The method of claim 7, further including backgrinding to reduce a thickness of the semiconductor wafer while the semiconductor wafer is attached to the carrier.

12. The method of claim 7, further including applying the microwave energy at a frequency of between 1 and 10 GHz.

13. The method of claim 7, further including applying microwave energy to keep a temperature of the semiconductor wafer between 100 and 180 degrees Celsius.

14. A method of making a semiconductor device, comprising:
providing a carrier;
disposing an adhesive coating over the carrier;
attaching a semiconductor die to the carrier using the adhesive coating; and
debonding the semiconductor die from the carrier by applying microwave energy to the adhesive coating.

15. The method of claim 14, further including applying the microwave energy at a frequency of between 1 and 10 GHz.

16. The method of claim 14, further including providing the carrier to include ceramic or glass, wherein the microwave energy is transmitted through the carrier to the adhesive coating.

17. The method of claim 14, further including:
disposing a microwave emitter over the carrier opposite the semiconductor die; and
generating the microwave energy using the microwave emitter.

18. The method of claim 14, further including backgrinding to reduce a thickness of the semiconductor die while the semiconductor die is attached to the carrier.

19. The method of claim 18, further including:
depositing an encapsulant over the semiconductor die; and
backgrinding the encapsulant and semiconductor die.

20. A semiconductor device, comprising:
a carrier;
a semiconductor die; and
an adhesive coating disposed between the carrier and semiconductor die, wherein the adhesive coating includes polypropylene carbonate and either a photo acid generator or thermal acid generator.

21. The semiconductor device of claim 20, wherein the carrier includes ceramic or glass.

22. The semiconductor device of claim 20, further including a microwave emitter disposed over the carrier opposite the semiconductor die.

23. The semiconductor device of claim 22, wherein the microwave emitter is configured to apply the microwave energy at a variable frequency between 1 and 10 GHz.

24. The semiconductor device of claim 20, further including an encapsulant deposited over the semiconductor die and carrier.

25. The semiconductor device of claim 20, wherein the adhesive coating includes a graphite powder.
